(19) United States
(12) Patent Application Publication
(10) Pub. No.: US 2002/0102799 A1
(43) Pub. Date: Aug. 1, 2002

(54) Method for the integrated production of EEPROM and FLASH memory cells

(76) Inventors: Peter Wawer, Dresden (DE); Elard Stein Von Kamienski, Dresden (DE); Christoph Ludwig, Langebruck (DE)

Correspondence Address: LERNER AND GREENBERG, P.A., POST OFFICE BOX, HOLLYWOOD, FL, 33022-2480, US

(21) Appl. No.: 09/835,344

(22) Filed: Apr. 16, 2001

(30) Foreign Application Priority Data
Feb. 1, 2001 (DE) 101 04 566.2

(51) Int. Cl. H01L 21/336

(52) U.S. Cl. 438/301; 438/266; 438/306

(57) ABSTRACT

EEPROM and FLASH memory cells are formed together in integrated production. A gate finger is used for implementing a homogeneous tunnel diffusion region for the EEPROM memory cell. This allows the different memory cells to be produced in a particularly simple and inexpensive manner.

### BACKGROUND OF THE INVENTION

Field of the Invention

The invention lies in the integrated technology field and pertains, more specifically, to a method for the integrated production of EEPROM and FLASH memory cells. The invention relates especially to a method for the simultaneous production of EEPROM and FLASH semiconductor memory cells.

Rewritable non-volatile semiconductor memory cells are becoming increasingly important in large-scale-integrated circuits since they can store variable data over a long period and without using a supply voltage, for example in chip cards or so-called smart cards.

Depending on the type of non-volatile semiconductor memory cells used, a basic distinction is made between EEPROM and FLASH memories and the associated memory cells, respectively.

FIGS. 1A to 1C show simplified sectional views for illustrating a production method for EEPROM memory cells according to the prior art.

With reference to FIG. 1A, a tunnel diffusion region TD is first formed by means of a tunnel implantation I1 in a semiconductor substrate 1 or, respectively, an active area formed therein. This provides a homogeneous diffusion region which enables a uniform potential distribution to be obtained. According to FIG. 1B, a tunnel layer 2 is formed in a tunnel area TB above the tunnel diffusion region TD and a high-voltage insulating layer 2a is formed in a switching transistor area ST in the subsequent production steps. This is followed by a layered formation of a charge-storing layer 3, a coupling layer 4, and a control layer 5 which are located both above the tunnel area TB and above the switching transistor area ST. Finally, with reference to FIG. 1C, a further implantation I2 is performed, preferably by using the mask consisting of the sequence of layers of the insulating layer 2 or 2a, respectively, the charge-storing layer 3, the coupling layer 4 and the control layer 5, for generating source/drain regions S/D.

This provides an EEPROM memory cell. The switching characteristic of the switching transistor area ST is influenced by the charges stored in the charge-storing layer 3. These charges are preferably introduced by Fowler-Nordheim tunneling in the tunnel area TB via the tunnel layer 2 into the charge-storing layer 3, the homogeneous tunnel diffusion region TD, in particular, with its uniform potential distribution providing for high endurance or, respectively, a high number of write/erase cycles (10⁵). The disadvantage in such EEPROM memory cells is, however, the relatively high requirement for area which is why the use of so-called FLASH memory cells is also demanded in a multiplicity of integrated circuits.

FIGS. 2A to 2C show simplified sectional views for illustrating essential method steps in the production of such FLASH memory cells. In contrast with the production of EEPROM memory cells, no tunnel diffusion region is formed in a first production step according to FIG. 2A in the production of FLASH memory cells. Instead, a sequence of layers consisting of a tunnel layer 2, a charge-storing layer 3, a coupling layer 4, and a control layer 5 is formed on a semiconductor substrate 1. See FIG. 2B. The sequence of layers is patterned to form a gate layer stack, and subsequently source/drain regions S/D are formed in the semiconductor substrate or, respectively, active area of the semiconductor substrate 1 by means of only a single implantation according to FIG. 2C. The implantation is performed in such a manner as that an underdiffusion under the tunnel layer 2 acting as tunnel area is obtained both at the source and at the drain end. This provides a semiconductor memory cell having a minimum requirement for area, the charge-storing layer 3 of which can be programmed both via Fowler-Nordheim tunneling and via injection of hot charge carriers or channel injection. The disadvantageous factor in such FLASH memory cells is, however, the relatively low endurance of a few 10³ write/erase cycles.

Future systems or semiconductor circuits are intended to provide increased functionality and performance for complex applications which is why the development of both types of cell is mandatory.

To implement semiconductor circuits with FLASH and EEPROM memory cells, the different and mutually independent technologies and production processes described above have therefore been usually implemented. Due to the different technologies, a multiplicity of additional masks and implantation steps were produced in the integrated production of EEPROM and FLASH memory cells which made production much more expensive and difficult.

### SUMMARY OF THE INVENTION

The object of the present invention is to provide a method which overcomes the above-noted deficiencies and disadvantages of the prior art devices and methods of this general kind, and which provides for a method for the integrated production of EEPROM and FLASH memory cells which has simplified production steps and is thus cost-effective.

With the above and other objects in view there is provided, in accordance with the invention, a method for the integrated production of EEPROM and FLASH memory cells, which comprises the following steps:

a) forming active areas for an EEPROM memory cell and a FLASH memory cell in a substrate;

b) simultaneously forming, for the EEPROM and FLASH memory cells, a tunnel layer, a charge-storing layer, a coupling layer, and a control layer;

c) simultaneously patterning, for the EEPROM and FLASH memory cells, the control layer, the coupling layer, the charge-storing layer, and the tunnel layer for forming a FLASH gate stack of the FLASH memory cell and an EEPROM gate stack with a gate finger of the EEPROM memory cell; and

d) simultaneously forming source/drain regions of the FLASH memory cells and the EEPROM memory cells in the substrate and thereby forming a homogeneous tunnel diffusion region in a tunnel area underneath the gate finger.

Due, in particular, to the simultaneous forming of a tunnel layer, a charge-storing layer, a coupling layer and a control layer for the EEPROM and FLASH memory cells and a patterning of the respective gate stack performed in such a manner that an EEPROM gate stack has a gate finger, the homogeneous tunnel diffusion region of which forms simultaneously with the source and drain regions of the memory cells, a homogeneous tunnel diffusion region can be formed at the same time with the source/drain regions of at least the FLASH memory cells without using additional implantation steps and/or mask steps which results in considerable simplification and cost saving.

In accordance with an added feature of the invention, the source/drain regions and the tunnel diffusion region are formed in self-alignment by implantation. The gate stacks are thereby used as implantation masks. The production method can be further simplified in this manner.

In accordance with an additional feature of the invention, a high-voltage insulating layer is formed in the gate stack of the EEPROM memory cell in addition to or instead of the tunnel layer. The high-voltage insulating layer improves the electrical characteristics of the cell and further increases the endurance of the memory cell.

In accordance with another feature of the invention, the source/drain regions and the tunnel diffusion region are formed with an LDD implantation process. In other word, the source/drain regions and the tunnel diffusion region are preferably formed by means of an LDD implantation which is performed on one or both sides. Such LDD implantations are usually available in every standard process as a result of which the method can be integrated into any standard processes.

In accordance with a further feature of the invention, in the patterning of the EEPROM gate stack with the gate finger and the FLASH gate stack, the gate finger is formed with a width that is smaller than a width of the FLASH gate stack. In other words, the EEPROM gate stack is preferably patterned with its tunnel finger and the FLASH gate stack in such a manner that a width of the tunnel finger is less than a width of the FLASH gate stack as a result of which the formation of a homogeneous tunnel diffusion region with uniform potential distribution in the tunnel area is implemented in a particularly reliable manner.

Furthermore, the EEPROM gate stack is patterned in such a manner that its tunnel area is spatially separate from its switching transistor area. This further simplifies the implementation of the underdiffusion under the tunnel layer for forming a homogeneous tunnel diffusion region.

In accordance with again an additional feature of the invention, tunnel fingers are formed in the substrate during the forming of the active areas for the EEPROM memory cells. In accordance with again another feature of the invention, the tunnel layer is formed as a thermally formed SiO₂ layer.

In accordance with again a furthere feature of the invention, the charge-storing layer is formed as an electrically conductive polysilicon layer.

In accordance with a concomitant feature of the invention, the coupling layer is formed as an ONO sequence of layers.

Other features which are considered as characteristic for the invention are set forth in the appended claims.

Although the invention is illustrated and described herein as embodied in a method for the integrated production of EEPROM and FLASH memory cells, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIGS. 1A to 1C are simplified sectional views for illustrating a prior art production method of an EEPROM memory cell;

FIGS. 2A to 2C are simplified sectional views for illustrating a prior art production method of a FLASH memory cell;

FIG. 3 is a simplified diagrammatic plan view onto an EEPROM and FLASH memory cell formed in a common substrate; and

FIGS. 4A and 4B are simplified sectional views taken along the section lines I-I′ and II-II′ in FIG. 2, and illustrating essential method steps according to the invention.

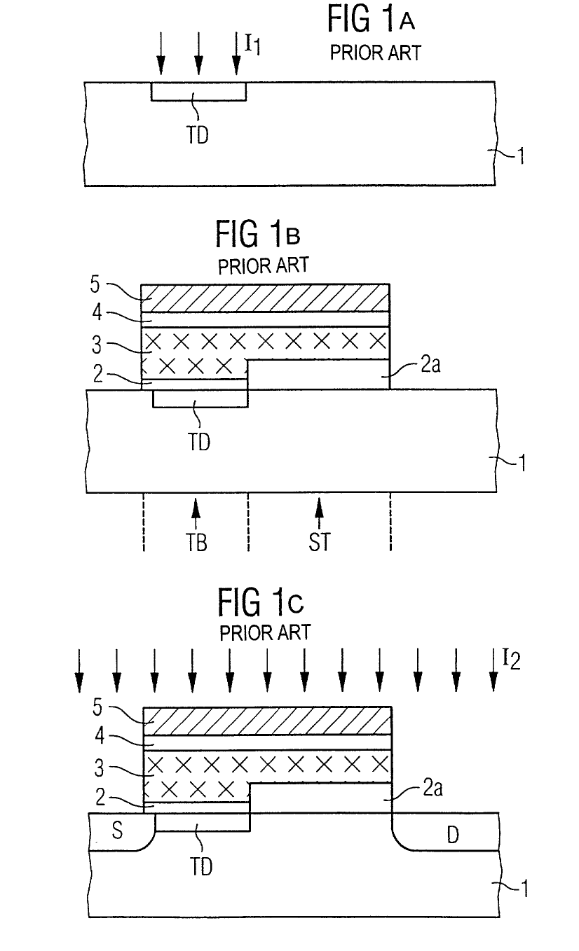

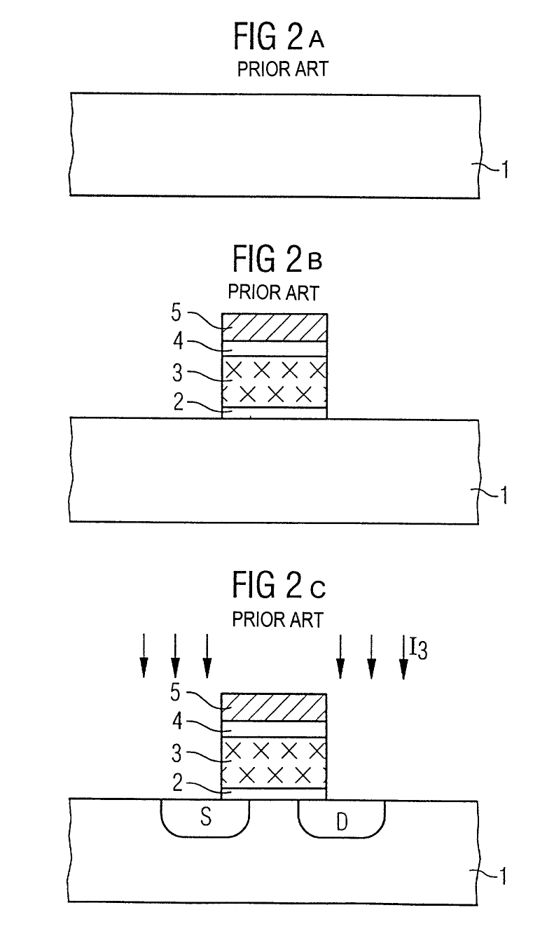

### DESCRIPTION OF THE PREFERRED EMBODIMENTS

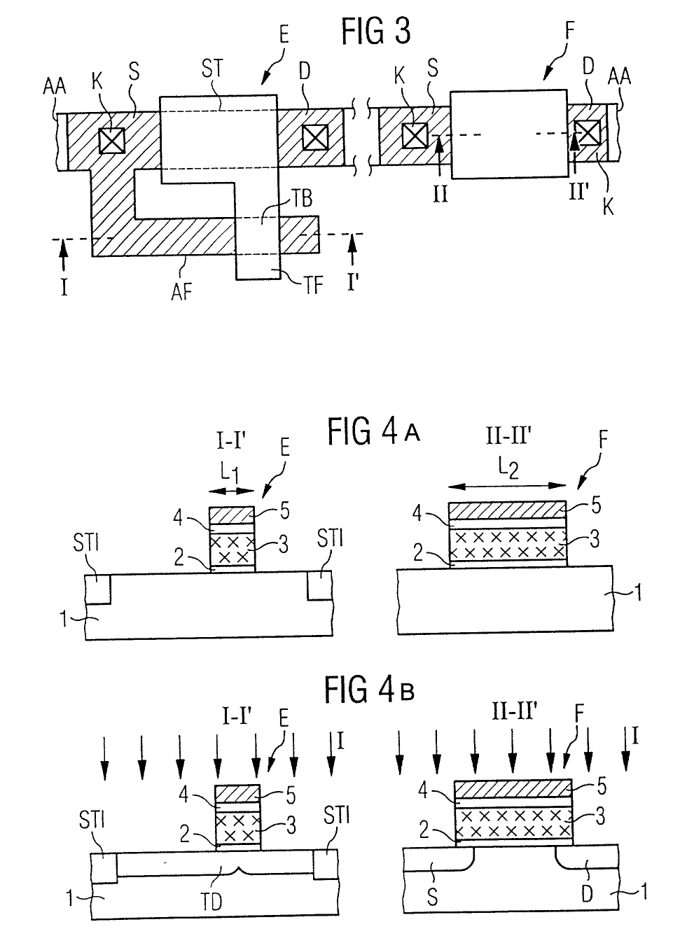

Referring now to the figures of the drawing which illustrate the invention in detail and first, particularly, to FIG. 3 thereof, there is seen a simplified top view of the layout of the EEPROM and FLASH memory cells formed in an integrated production method.

Active areas AA which are essentially patterned in the form of strips for a FLASH memory cell F and have, for example, a tunnel finger AF in the substrate for an EEPROM memory cell E, are formed, for example, by means of shallow trench isolation (STI) in a semiconductor substrate. A sequence of layers of essentially a tunnel layer 2, a charge-storing layer 3, a coupling layer 4, and a control layer 5—see the sectional views of FIGS. 4A and 4B—overlaps the active area AA, and is formed on the substrate surface.

In this configuration, the control layer 5 is used as top layer of the activation of the respective EEPROM and FLASH memory cell, as a result of which a channel lying underneath is switched through in dependence on charges stored in the charge-storing layer 3. In addition, the EEPROM memory cell E also has in its gate stack consisting of a sequence of layers a gate finger TF for forming a tunnel area TB together with the tunnel finger AF in the substrate or, respectively, active area AA. A charge-storing layer 3 lying over the tunnel area TB is electrically conductively connected to a charge-storing layer in a switching transistor area ST as a result of which the switching characteristics of the latter, in turn, can be changed in dependence on the stored charges.

To form a field-effect transistor, source and drain regions S and D which, for example, are connected via contacts K and provide an operative memory cell, are located adjacently to the left and to the right of the respective gate stacks or, respectively, the sequence of layers. The EEPROM memory cell E and/or FLASH memory cell F produced in the integrated method described hereinafter essentially corresponds to conventional EEPROM and FLASH memory cells. Accordingly, a detailed description will be dispensed with in the following text.

The novel factor, however, is the special production method by means of which the different memory cell types described above can be produced in a particularly simple and inexpensive, integrated manner that is to say in a common production process.

FIGS. 4A and 4B show simplified sectional views of essential production steps along section I-I′ and II-II′ according to FIG. 3. Identical reference symbols here designate identical or corresponding elements or layers which is why a repeated description will not be given in the text that follows.

According to FIG. 4A, active areas AA for the EEPROM and FLASH memory cells E and F are first formed in first production steps in the semiconductor substrate 1 which consists, for example, of silicon SOI or another suitable substrate. The active areas AA are preferably formed by means of a shallow trench isolation STI in the semiconductor substrate 1 but other methods (such as, for example, LOCOS) are also possible. In a subsequent step, the tunnel layer 2 is next formed with its entire area on the surface of the substrate 1, or at least for the tunnel area TB and the FLASH memory cell F. This tunnel layer 2 is preferably formed thermally by means of a conventional furnace process or by means of a rapid thermal process (RTP) as a silicon dioxide layer which produces isolation layers or tunnel layers of very high quality.

As substitute or in addition, a high-voltage insulating layer 2A as is known from the prior art can optionally be formed in the area of the switching transistor area ST of the EEPROM memory cell. For the simultaneous forming with the tunnel layer 2, a preparatory implantation of oxide growth inhibitors in the tunnel areas is possible here, for example, as a result of which different oxide thicknesses can be generated in the tunnel area and/or high-voltage area in one production step. In this manner, the EEPROM memory cell can achieve a particularly high endurance of up to 10⁵ write/erase cycles. The high-voltage insulating layer 2A consists, for example, of a high-voltage gate oxide (HVGOX) with a layer thickness which is much greater than that of the tunnel layer 2.

After that, a charge-storing layer 3 which is used for storing the charges introduced via the tunnel layer 2 is formed with its whole area on the surface of the tunnel layer 2 or, respectively, the high-voltage insulating layer. For example, a polysilicon layer doped in situ is deposited as such a charge-storing layer 3 but other electrically conductive and charge-storing layers can also be used. For example, undoped (amorphous) polysilicon can be deposited, which is doped at a later time, for example, by means of implantation.

To isolate the charge-storing layer 3 from a control layer 5 formed subsequently, a coupling layer 4 is formed with its whole area on the surface of the charge-storing layer 3 and then the control layer 5 is generated. The coupling layer 4 is essentially used for coupling the potentials applied to the control layer 5 into the charge-storing layer 3 as a result of which charge carriers can be tunneled via the tunnel layer 2 into the charge-storing layer 3. The coupling layer 4 preferably consists of a sequence of layers ONO with an oxide/nitride/oxide which provides for very good insulating characteristics and is simple to produce.

The control layer 5 consists, for example, of a metallic layer or of a highly doped polysilicon layer that can, however, also have other electrically conductive layers.

According to FIG. 4A, in contrast to the prior art, both the active area AA and the layers described above are simultaneously formed both for the EEPROM memory cell E and the FLASH memory cell F which is why no additional precipitation steps are necessary.

Since, however, the implantation step for forming a tunnel diffusion region TD, which is necessary, in particular, for producing an EEPROM memory cell E in the conventional method, has not yet taken place and is not to be performed either, the gate stack of the EEPROM memory cell E, in particular, is patterned in a subsequent patterning step according to FIG. 4A in such a manner that it has a gate finger TF, overlapping the tunnel finger AF of the substrate 1, with the sequence of layers described above but only a width L1 which is smaller than a width L2 of the FLASH memory cell F patterned at the same time.

More precisely, the gate finger TF is patterned in such a manner that its width L1 is so small that in a subsequent implantation step or associated annealing steps, a complete underdiffusion for forming a homogeneous tunnel diffusion region TD is produced while only a partial underdiffusion under the gate stack with the greater width L2 takes place in the FLASH memory cell F formed at the same time.

FIG. 4B shows a simplified sectional view of such an implementation step in which, with a simultaneous implantation I for forming the source and drain regions S and D of, in particular, the FLASH memory cell F but also of the EEPROM memory cell E, a complete underdiffusion takes place for forming a homogeneous tunnel diffusion region TD in the area of the tunnel finger AF of the substrate 1 and of the gate finger TF of the gate stack. A small indentation of the tunnel diffusion region TD due to the regions abutting in each case does not have a disadvantageous effect on the endurance of the memory cell. This, in turn, produces an EEPROM memory cell E having a uniform potential distribution in its tunnel area TB which results in extremely high endurances or, respectively an endurance of up to 10⁵ cycles. At the same time, however, a FLASH memory cell E can also be formed without using additional mask or implantation steps, which although it has lower endurances of up to only 10³ write/erase cycles, needs much less area.

The source and drain regions S and D can have a greater overlap area under the gate stack on one or both sides. The source/drain regions S and D and tunnel diffusion region TD are preferably formed by means of an LDD implantation which exists in many standard processes. However, other implantations can also be used for implementing the source/drain regions and the tunnel diffusion region.

When an implantation I is used, in particular, the source and drain regions S/D and the tunnel diffusion region TD can be formed in a self-aligning manner by means of the gate stacks used as a mask. By patterning the EEPROM gate stack to form a gate finger TF, a tunnel area TB can be advantageously spatially separated from a switching transistor area ST as a result of which the tunnel diffusion region TD is obtained in a particularly simple manner by underdiffusion on both sides of the tunnel finger TF. However, the gate finger TF can also directly adjoin the switching transistor area ST which results in simplified patterning both of the active area AA and the gate stack for the EEPROM memory cell.

A description of the further steps for completing the EEPROM and FLASH memory cells and for forming the further isolating and metallization layers with their associated contacts K will be omitted here, because they are sufficiently well known to those of skill in the art.

The invention provides a method for the integrated production of EEPROM and FLASH memory cells which can be formed in a particularly inexpensive and simple manner. Accordingly, the respective advantages of EEPROM and FLASH memory cells can be carried out in an especially advantageous manner in a common semiconductor circuit without additional lithography, mask or implantation steps. The programming of the FLASH memory cells in particular is not limited to Fowler-Nordheim tunneling but also provides for selection by means of injection of hot charge-carriers (CHE, channel hot electrons).

We claim:

1. A method for the integrated production of EEPROM and FLASH memory cells, which comprises the following steps:
a) forming active areas for an EEPROM memory cell and a FLASH memory cell in a substrate;
b) simultaneously forming, for the EEPROM and FLASH memory cells, a tunnel layer, a charge-storing layer, a coupling layer, and a control layer;
c) simultaneously patterning, for the EEPROM and FLASH memory cells, the control layer, the coupling layer, the charge-storing layer, and the tunnel layer for forming a FLASH gate stack of the FLASH memory cell and an EEPROM gate stack with a gate finger of the EEPROM memory cell; and
d) simultaneously forming source/drain regions of the FLASH memory cells and the EEPROM memory cells in the substrate and thereby forming a homogeneous tunnel diffusion region in a tunnel area underneath the gate finger.

2. The method according to claim 1, wherein step d) comprises forming the source/drain regions and the tunnel diffusion region in self-alignment by implantation and thereby using the gate stacks as implantation masks.

3. The method according to claim 1, which comprises forming a high-voltage insulating layer in the gate stack of the EEPROM memory cell in addition to the tunnel layer.

4. The method according to claim 1, wherein the step of forming the tunnel layer comprises forming a high-voltage insulating layer in the gate stack of the EEPROM memory cell.

5. The method according to claim 1, which comprises forming the source/drain regions and the tunnel diffusion region with an LDD implantation process.

6. The method according to claim 1, wherein the step of patterning the EEPROM gate stack with the gate finger and the FLASH gate stack comprises forming the gate finger with a width smaller than a width of the FLASH gate stack.

7. The method according to claim 1, wherein the steps of patterning the EEPROM gate stack and the active area comprises forming the tunnel area spatially separate from a switching transistor area.

8. The method according to claim 1, which comprises forming tunnel fingers in the substrate during the forming of the active areas for the EEPROM memory cells.

9. The method according to claim 1, which comprises forming the tunnel layer as a thermally formed SiO₂ layer.

10. The method according to claim 1, which comprises forming the charge-storing layer as an electrically conductive polysilicon layer.

11. The method according to claim 1, which comprises forming the coupling layer as an ONO sequence of layers.
